(19) United States
(12) Patent Application Publication
(10) Pub. No.: US 2025/0191986 A1
(43) Pub. Date: Jun. 12, 2025

(54) SEMICONDUCTOR PACKAGES INCLUDING MOLDING GUIDE PATTERNS

(71) Applicant: SAMSUNG ELECTRONICS CO., LTD., Suwon-si (KR)

(72) Inventors: Gyuhyeong Kim, Suwon-si (KR); Yongkwan Lee, Suwon-si (KR); Seunghwan Kim, Suwon-si (KR); Jungjoo Kim, Suwon-si (KR); Junwoo Park, Suwon-si (KR); Junhyeung Jo, Suwon-si (KR)

(21) Appl. No.: 18/787,401

(22) Filed: Jul. 29, 2024

(30) Foreign Application Priority Data
Dec. 11, 2023 (KR) 10-2023-0178742

(51) Int. Cl. H01L 23/31; H01L 21/56; H01L 23/00; H01L 23/24; H01L 23/498

(52) U.S. Cl. CPC H01L 23/3107; H01L 23/24; H01L 24/16; H01L 24/17; H01L 21/56; H01L 23/49816; H01L 23/49822; H01L 2224/16227; H01L 2224/1712

(57) ABSTRACT

A semiconductor package includes a package substrate, a lower molding guide pattern disposed over the package substrate and including a first portion and a second portion, a semiconductor chip disposed over an upper surface of the package substrate and over an upper surface of the first portion of the lower molding guide pattern, an upper molding guide dam over the second portion of the lower molding guide pattern, and a molding layer covering a side surface of the semiconductor chip and extending between the package substrate and a lower surface of the semiconductor chip, wherein the upper molding guide dam is disposed laterally with respect to the semiconductor chip.

### CROSS-REFERENCE TO RELATED APPLICATION

This application claims priority under 35 U.S.C. § 119 to Korean Patent Application No. 10-2023-0178742, filed on Dec. 11, 2023, in the Korean Intellectual Property Office, the disclosure of which is incorporated by reference herein in its entirety.

### BACKGROUND

Semiconductor packages are integrated circuit chips implemented in forms suitable for use in electronic products. Generally, in a semiconductor package, a semiconductor chip is mounted on a printed circuit board and they are electrically connected to each other by using bonding wires or bumps. With the development of the electronics industry, various researches have been conducted to improve the characteristics of semiconductor packages and reduce the defects thereof.

### SUMMARY

Some implementations according to this disclosure provide semiconductor packages with improved performance and reliability and/or reduced defects, and methods of manufacturing the same.

According to some implementations, there is provided a semiconductor package including a package substrate, a lower molding guide pattern disposed over the package substrate and including a first portion and a second portion, a semiconductor chip disposed over an upper surface of the package substrate and over an upper surface of the first portion of the lower molding guide pattern, an upper molding guide dam over the second portion of the lower molding guide pattern, and a molding layer covering a side surface of the semiconductor chip and extending between the package substrate and a lower surface of the semiconductor chip, wherein the upper molding guide dam is disposed laterally with respect to the semiconductor chip.

According to some implementations, there is provide a semiconductor package including a substrate, lower insulating patterns provided over the substrate and spaced apart from each other in a first direction, upper insulating patterns provided over the lower insulating patterns and spaced apart from each other in the first direction, a semiconductor chip provided over an upper surface of the substrate and disposed between inner walls of the upper insulating patterns, bumps between the substrate and the semiconductor chip, and a molding layer covering a sidewall of the semiconductor chip and extending between the bumps, wherein each of the lower insulating patterns includes a first portion provided between the substrate and the semiconductor chip, and a second portion spaced apart from the semiconductor chip and overlapping one of the upper insulating patterns in a plan view.

According to some implementations, there is provided a semiconductor package including a package substrate including an insulating layer, substrate wires, and a protection layer, solder ball terminals on a lower surface of the package substrate, lower molding guide patterns provided over an upper surface of the package substrate and spaced apart from each other in a first direction, upper molding guide dams respectively disposed over the lower molding guide patterns and spaced apart from each other in the first direction, a semiconductor chip provided over the upper surface of the package substrate and disposed between the upper molding guide dams, bumps disposed between the upper surface of the package substrate and a lower surface of the semiconductor chip and electrically connected to the package substrate and the semiconductor chip, and a molding layer disposed over the upper surface of the package substrate and covering a side surface of the semiconductor chip, wherein the molding layer extends under the lower surface of the semiconductor chip to cover sidewalls of the bumps, each of the lower molding guide patterns includes a first portion disposed between the substrate and the semiconductor chip, and a second portion spaced apart from the semiconductor chip and overlapping one of the upper molding guide dams in a plan view, an upper surface of the first portion of each of the lower molding guide patterns is provided at a lower level than the lower surface of the semiconductor chip, and upper surfaces of the upper molding guide dams are provided at a level that is higher than or equal to a level of the lower surface of the semiconductor chip and is lower than a level of an upper surface of the semiconductor chip.

### BRIEF DESCRIPTION OF THE DRAWINGS

Implementations will be more clearly understood from the following detailed description taken in conjunction with the accompanying drawings in which:

FIG. 1A is a plan view illustrating a semiconductor package according to some implementations;

FIG. 1B is a cross-sectional view of a semiconductor package taken along line I-I′ of FIG. 1A;

FIG. 1C is a cross-sectional view illustrating a substrate and lower molding guide patterns according to some implementations;

FIG. 1D is a cross-sectional view illustrating lower molding guide patterns and upper molding guide dams according to some implementations;

FIG. 1E is a cross-sectional view illustrating a substrate, lower molding guide patterns, and upper molding guide dams according to some implementations;

FIGS. 2A to 2D are diagrams illustrating a process of manufacturing a semiconductor package according to some implementations;

FIG. 3A is a plan view illustrating a process of forming a molding layer;

FIG. 3B is a cross-sectional view taken along line I-I′ of FIG. 3A;

FIG. 3C is a cross-sectional view taken along line II-II′ of FIG. 3A;

FIG. 3D is a cross-sectional view illustrating a molding layer;

FIG. 4A is a plan view illustrating a process of forming a molding layer according to some implementations;

FIG. 4B is a cross-sectional view taken along line I-I′ of FIG. 4A;

FIG. 4C is a cross-sectional view taken along line II-II′ of FIG. 4A;

FIG. 5A is a plan view illustrating a semiconductor package according to some implementations;

FIG. 5B is a cross-sectional view of a semiconductor package taken along line I-I′ of FIG. 5A;

FIG. 5C is a cross-sectional view of a semiconductor package taken along line III-III′ of FIG. 5A;

FIG. 6A is a plan view illustrating a semiconductor package according to some implementations;

FIG. 6B is a cross-sectional view of a semiconductor package taken along line I-I′ of FIG. 6A; and

FIG. 7 is a plan view illustrating a semiconductor package according to some implementations.

### DETAILED DESCRIPTION

Herein, like reference numerals may refer to like elements throughout.

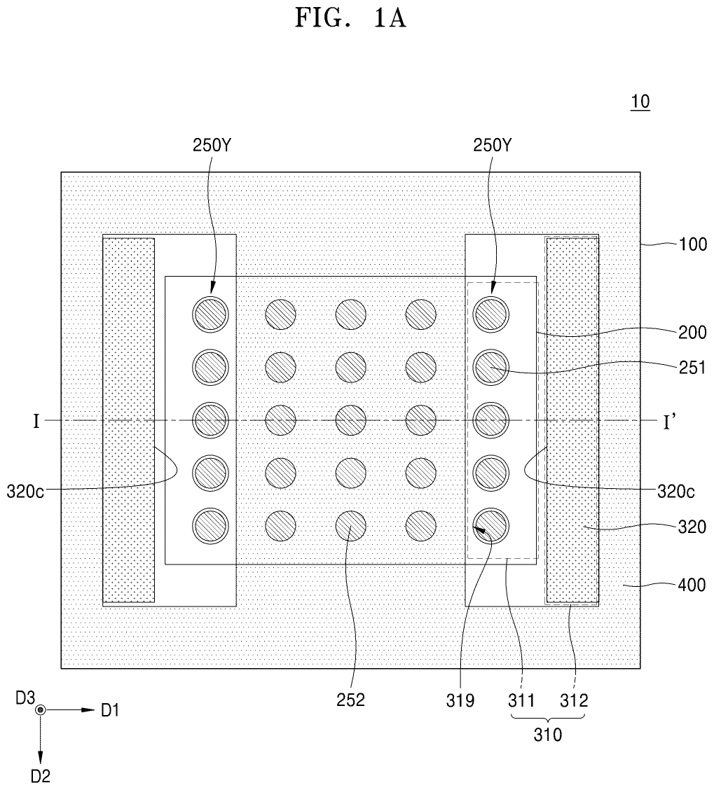

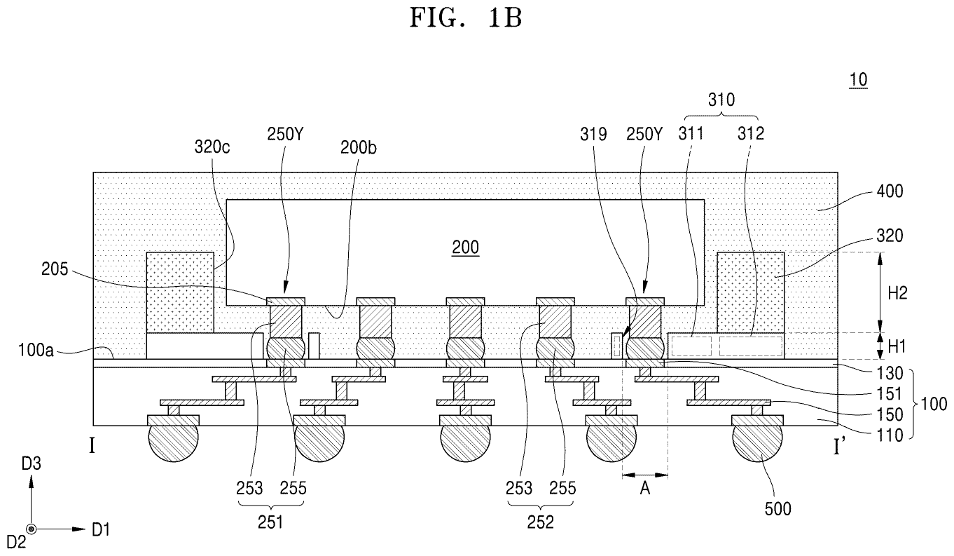

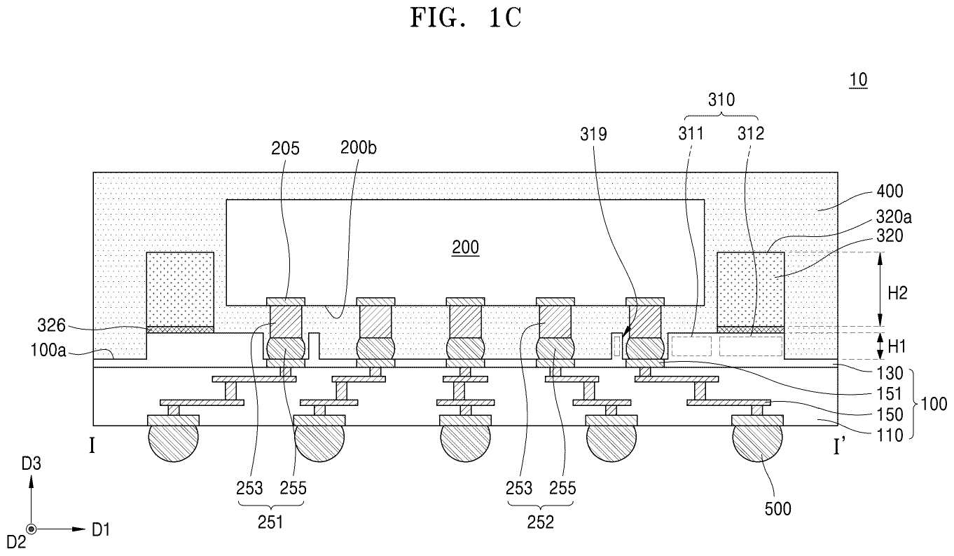

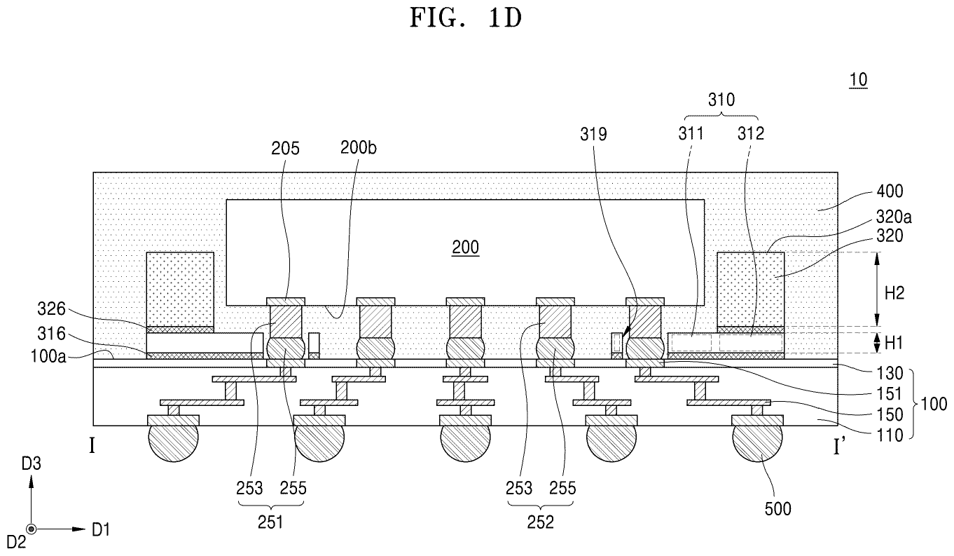

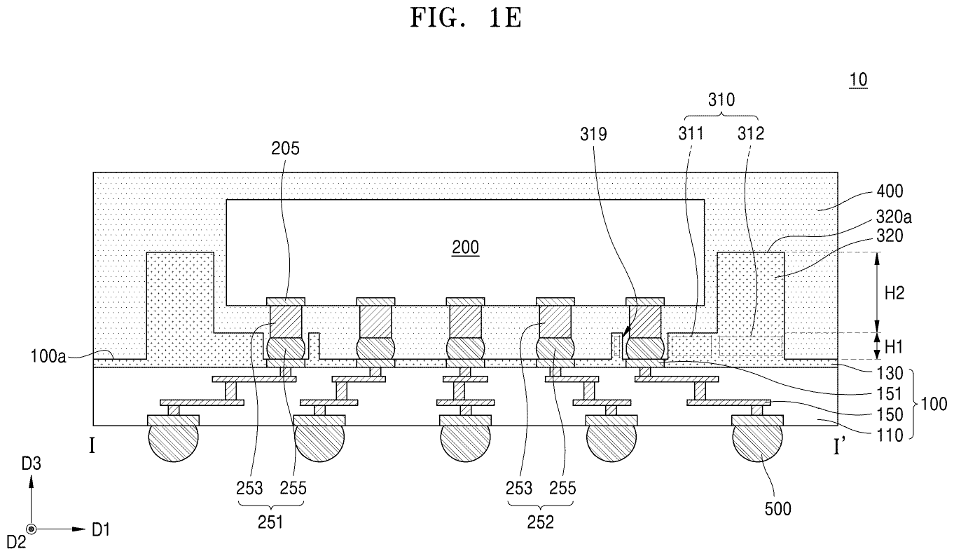

FIG. 1A is a plan view illustrating a semiconductor package according to some implementations. FIG. 1B is a cross-sectional view of the semiconductor package taken along line I-I′ of FIG. 1A.

Referring to FIGS. 1A and 1B, the semiconductor package 10 may include a substrate, solder ball terminals 500, a semiconductor chip 200, first bumps 251, second bumps 252, a lower molding guide pattern 310, an upper molding guide dam 320, and a molding layer 400.

The substrate may be a package substrate 100. The package substrate 100 may include an insulating layer 110, a protection layer 130, substrate wires (e.g., wiring such as traces, interconnects, vias, etc.) 150, and upper substrate pads 151. For example, a printed circuit board may be used as the package substrate 100. The insulating layer 110 may include a plurality of layers. The insulating layer 110 may include at least one of insulating resin and glass fiber. As an example, the insulating layer 110 may include prepreg. In some implementations, a rewiring layer may be used as the package substrate 100.

The upper substrate pads 151 may be provided over or at an upper surface 100a of the package substrate 100. The substrate wires 150 may be provided in the package substrate 100 and may be connected to the upper substrate pads 151. Components provided in the package substrate 100 may include components provided in the insulating layer 110. An electrical connection to the package substrate 100 may mean an electrical connection to at least one of the substrate wires 150. An electrical connection of two elements to each other may include a direct connection or an indirect connection through another element. The substrate wires 150 and the upper substrate pads 151 may include metal such as copper, aluminum, tungsten, and/or titanium.

The protection layer 130 may be provided over the insulating layer 110 to cover the upper surface of the insulating layer 110. When the insulating layer 110 includes a plurality of layers, the protection layer 130 may cover the upper surface of the uppermost insulating layer 110. The upper surface 100a of the package substrate 100 may include the upper surface of the protection layer 130. The protection layer 130 may further cover, for example, the upper surfaces of the edge portions of the upper substrate pads 151 and/or the sidewalls of the upper substrate pads 151; however, the arrangement is not limited thereto. The protection layer 130 may include an insulating polymer. The protection layer 130 may include a different material than the insulating layer 110. For example, the protection layer 130 may include a solder resist material.

A first direction D1 may be parallel to the upper surface 100a of the package substrate 100. A second direction D2 may be parallel to the upper surface 100a of the package substrate 100 and intersect the first direction D1. For example, the second direction D2 may be perpendicular to the first direction D1. A third direction D3 may be perpendicular to the upper surface 100a of the package substrate 100.

The solder ball terminals 500 may be provided on the lower surface of the package substrate 100. The solder ball terminals 500 may be electrically connected to the upper substrate pads 151 through the substrate wires 150. External electrical signals may be transmitted to the package substrate 100 through the solder ball terminals 500. The solder ball terminals 500 may include a solder material. The solder material may include, for example, tin, silver, bismuth, or any alloy thereof.

The semiconductor chip 200 may be mounted on the upper surface 100a of the package substrate 100. As an example, the semiconductor chip 200 may include a logic chip such as an application processor (AP) chip. As another example, the semiconductor chip 200 may include a memory chip. The semiconductor chip 200 may include integrated circuits and chip pads 205. The integrated circuits may be provided in the semiconductor chip 200 and may be disposed adjacent to a lower surface 200b of the semiconductor chip 200. The chip pads 205 may be disposed on the lower surface 200b of the semiconductor chip 200 and may be electrically connected to the integrated circuits. Being electrically connected to the semiconductor chip 200 may mean being electrically connected to the integrated circuits of the semiconductor chip 200 through the chip pads 205.

Bumps 251 and 252 may include first bumps 251 and second bumps 252. The first and second bumps 251 and 252 may be disposed between the package substrate 100 and the semiconductor chip 200 and may be connected to the upper substrate pads 151 and the chip pads 205. The first and second bumps 251 and 252 may form an array arranged along rows and columns in the plan view as illustrated in FIG. 1A. The rows may be parallel to the first direction D1, and the columns may be parallel to the second direction D2. The first bumps 251 may be outer bumps. The first bumps 251 may include bumps in outer columns. The first bumps 251 may include, for example, bumps in outermost columns 250Y. For example, the outermost columns 250Y may correspond to the outermost columns among the columns formed by the first and second bumps 251 and 252. The second bumps 252 may be inner bumps. For example, the second bumps 252 may be disposed between the first bumps 251. In the plan view, the columns formed by the second bumps 252 may be disposed between the outermost columns 250Y of the first bumps 251. The size and shape of the second bumps 252 may be substantially the same as the size and shape of the first bumps 251.

Each of the first and second bumps 251 and 252 may include a conductive pillar 253 and a solder ball 255. The conductive pillar 253 may be provided on the lower surface of a chip pad 205 corresponding thereto and may be connected to the chip pad 205. The conductive pillar 253 may include, for example, a metal such as copper. The solder ball 255 may be provided on the lower surface of the conductive pillar 253. The solder ball 255 may be bonded to the upper surface of an upper substrate pad 151 corresponding thereto among the upper substrate pads 151. The solder ball 255 may be electrically connected to the upper substrate pad 151. Accordingly, the semiconductor chip 200 may be electrically connected to the package substrate 100 through the first and second bumps 251 and 252. The solder ball 255 may include a different material than the conductive pillar 253 and the upper substrate pad 151. For example, the solder ball 255 may include a metal such as a solder material. The conductive pillar 253 of each of the second bumps 252 may be formed in a single process with the conductive pillar 253 of each of the first bumps 251. The material, shape, and size of the conductive pillar 253 of each of the second bumps 252 may be substantially the same as the material, shape, and size of the conductive pillar 253 of each of the first bumps 251. The solder ball 255 of each of the second bumps 252 may be formed in a single process with the solder ball 255 of each of the first bumps 251. The material, shape, and size of the solder ball 255 of each of the second bumps 252 may be substantially the same as the material, shape, and size of the solder ball 255 of each of the first bumps 251. The sizes, shapes, widths, lengths, levels, or thicknesses of certain elements being the same as each other or matching each other may mean that the values match within an error range that may occur in the process.

The lower molding guide pattern 310 may be provided over the upper surface 100a of the package substrate 100. The lower molding guide pattern 310 may protrude upward from the upper surface 100a of the package substrate 100.

The lower molding guide patterns 310 may be provided as a plurality of lower molding guide patterns 310. The lower molding guide patterns 310 may be disposed spaced apart from each other in the first direction D1. The lower molding guide patterns 310 may extend in the second direction D2. For example, the long sides of the lower molding guide patterns 310 may be parallel to the second direction D2.

Each of the lower molding guide patterns 310 may include a first portion 311 and a second portion 312. The second portion 312 of each of the lower molding guide patterns 310 may be disposed laterally with respect to the first portion 311 and may be connected to (e.g., in contact with) the first portion 311 without an intermediate layer or material therebetween. In some implementations, the second portion 312 of each of the lower molding guide patterns 310 may be spaced laterally apart from the first portion 311. The second portion 312 of each of the lower molding guide patterns 310 may be integrally formed with the first portion 311. The upper surface of each of the lower molding guide patterns 310 may be provided at a lower level than the lower surface 200b of the semiconductor chip 200. The upper surface of each of the lower molding guide patterns 310 may include the upper surface of the first portion 311 and the upper surface of the second portion 312. The upper surface of the second portion 312 of each of the lower molding guide patterns 310 may be provided at the same level as the upper surface of the first portion 311. Herein, the level of an element may refer to a vertical level measured in a vertical direction. The vertical direction may be the third direction D3.

The first portion 311 of each of the lower molding guide patterns 310 may overlap the semiconductor chip 200 in the plan view, e.g., may be at least partially under the semiconductor chip 200. For example, the first portion 311 of each of the lower molding guide patterns 310 may be disposed between the package substrate 100 and the semiconductor chip 200. That is, the semiconductor chip 200 may be disposed over the upper surface of the first portion 311 of each of the lower molding guide patterns 310. The upper surface of the first portion 311 of each of the lower molding guide patterns 310 may be vertically spaced apart from the lower surface 200b of the semiconductor chip 200. Accordingly, a first gap area may be provided between the upper surface of the first portion 311 of each of the lower molding guide patterns 310 and the lower surface 200b of the semiconductor chip 200.

The second portion 312 of each of the lower molding guide patterns 310 may be spaced laterally apart from the semiconductor chip 200 in the plan view. The second portion 312 of each of the lower molding guide patterns 310 may overlap the upper molding guide dam 320 described below, in the plan view.

The lower molding guide patterns 310 may include openings 319. The openings 319 may be provided over/in the first portion 311 of each of the lower molding guide patterns 310 and may not be provided over the second portion 312. For example, the openings 319 may be spaced apart from the second portion 312 of each of the lower molding guide patterns 310 in the plan view. The openings 319 may pass through the upper surface and lower surface of the first portion 311 of each of the lower molding guide patterns 310. The openings 319 may expose the upper substrate pads 151. The openings 319 may have a circular or elliptical shape in the plan view. A diameter A of the openings 319 may be about 90 μm to about 150 μm.

The first bumps 251 may be provided in the openings 319. For example, the openings 319 may be provided over the sidewalls of the first bumps 251. Because the diameter A of the openings 319 is 90 μm or more, the first bumps 251 may be provided in the openings 319. The second bumps 252 may not be provided in the openings 319. The second bumps 252 may be spaced apart from the openings 319 and the lower molding guide patterns 310. The second bumps 252 may be disposed between the lower molding guide patterns 310. Particularly, the second bumps 252 may be disposed between the inner walls of the lower molding guide patterns 310.

The lower molding guide patterns 310 may be lower insulating patterns. The lower molding guide patterns 310 may include an insulating material such as an insulating polymer. For example, the lower molding guide patterns 310 may include a solder resist material. As an example, the lower molding guide patterns 310 may include the same material as the protection layer 130; however, the materials are not limited thereto. For example, when the lower molding guide patterns 310 include the same material as the protection layer 130, the material composition ratio of the lower molding guide patterns 310 may be substantially equal to the material composition ratio of the protection layer 130. A height H1 of the lower molding guide patterns 310 may be about 15 μm to about 30 μm. The height H1 of the lower molding guide patterns 310 may be less than the height of the first bumps 251 and the height of the second bumps 252.

Upper molding guide dams 320 may be respectively provided over the lower molding guide patterns 310. The upper molding guide dams 320 may be disposed apart from each other in the first direction D1. The upper molding guide dams 320 may extend in the second direction D2 in the plan view. For example, the long sides of the upper molding guide dams 320 may be parallel to the second direction D2. The upper molding guide dams 320 may be disposed over a plurality of second portions 312 of the lower molding guide patterns 310. The upper molding guide dams 320 may be spaced apart from the upper surfaces of a plurality of first portions 311 of the lower molding guide patterns 310. The upper molding guide dams 320 may expose the upper surfaces of the first portions 311 of the lower molding guide dams 310 with respect to the upper molding guide dams 320. The width of each of the upper molding guide dams 320 may be less than the width of a lower molding guide pattern 310 corresponding thereto among the lower molding guide patterns 310.

Upper surfaces 320a of the upper molding guide dams 320 may be provided at a level higher than or equal to the level of the lower surface 200b of the semiconductor chip 200. The upper surfaces 320a of the upper molding guide dams 320 may be provided at a higher level than the lower surface 200b of the semiconductor chip 200. In some implementations, based at least on this configuration, the semiconductor package 10 may be miniaturized. A height H2 of the upper molding guide dams 320 may be greater than the height H1 of the lower molding guide patterns 310. The height H2 of the upper molding guide dams 320 may be about 45 μm to about 300 μm. In some implementations, because the height H2 of the upper molding guide dams 320 is 300 μm or less, the semiconductor package 10 may be miniaturized.

The upper molding guide dams 320 may be upper insulating patterns. The upper molding guide dams 320 may include an insulating material such as an insulating polymer. For example, the upper molding guide dams 320 may include a solder resist material. As an example, the upper molding guide dams 320 may include the same material as the lower molding guide patterns 310; however, the materials are not limited thereto.

In some implementations, the semiconductor chip 200 may be disposed laterally with respect to the upper molding guide dams 320, e.g., spaced laterally apart from the upper molding guide dams 320. The semiconductor chip 200 may be disposed between the upper molding guide dams 320. For example, the semiconductor chip 200 may be disposed between the inner sides of the upper molding guide dams 320.

The molding layer 400 may be disposed over the upper surface 100a of the package substrate 100 to cover the semiconductor chip 200, the lower molding guide patterns 310, and the upper molding guide dams 320. The molding layer 400 may cover the sidewalls of the semiconductor chip 200, the sidewalls of the lower molding guide patterns 310, the sidewalls of the upper molding guide dams 320, and the upper surfaces 320a of the upper molding guide dams 320. The molding layer 400 may further cover the upper surface of the semiconductor chip 200. The molding layer 400 may further extend between the upper surface 100a of the package substrate 100 and the lower surface 200b of the semiconductor chip 200 to cover the lower surface 200b of the semiconductor chip 200. The molding layer 400 may extend between the bumps 251 and 252 to cover the sidewalls of the bumps 251 and 252. The molding layer 400 may further fill a gap area between the upper surfaces of the first portions 311 of the lower molding guide patterns 310 and the lower surface 200b of the semiconductor chip 200. Because, in some implementations, the height H1 of the lower molding guide patterns 310 is 30 μm or less, the molding layer 400 may fill a first gap area between the upper surfaces of the first portions 311 of the lower molding guide patterns 310 and the lower surface 200b of the semiconductor chip 200. The molding layer 400 may further extend into the openings 319 to fill a second gap area between the first bumps 251 and the surfaces defining the openings 319. The molding layer 400 may include an insulating polymer such as an epoxy molding compound (EMC).

FIG. 1C is a diagram illustrating a substrate and lower molding guide patterns according to some implementations and corresponds to a cross-sectional view of the semiconductor package taken along line I-I′ of FIG. 1A. Hereinafter, redundant descriptions with those given above will be omitted for conciseness; descriptions provided with respect to FIGS. 1A and 1B apply equally to corresponding elements of FIG. 1C, except where noted otherwise or suggested otherwise by context.

Referring to FIGS. 1A and 1C, in some implementations, the lower molding guide patterns 310 may be connected to (e.g., in contact with) the protection layer 130 without an interface therebetween (e.g., without a gap or other layer therebetween) and may include the same material as the protection layer 130. For example, the lower molding guide patterns 310 may be integrally formed with the protection layer 130. The lower molding guide patterns 310 and the protection layer 130 may include a solder resist material. In this case, the composition ratio of the solder resist material of the lower molding guide patterns 310 may be substantially equal to the composition ratio of the solder resist material of the protection layer 130. The lower molding guide pattern 310 may protrude from the upper surface 100a of the package substrate 100 in the third direction D3, and the upper surface 100a of the package substrate 100 may correspond to the upper surface of the protection layer 130 spaced apart from the lower molding guide patterns 310.

The semiconductor package 10 may further include first adhesive layers 326. The first adhesive layers 326 may be respectively disposed on the lower surfaces of the upper molding guide dams 320. For example, the first adhesive layers 326 may attach the upper molding guide dams 320 to the lower molding guide patterns 310. The first adhesive layers 326 may be spaced apart from the upper surfaces of the first portions 311 of the lower molding guide patterns 310. The first adhesive layers 326 may include, for example, an insulating polymer. The first adhesive layers 326 may include a different material than the lower molding guide patterns 310 and the upper molding guide dams 320. The thickness of the first adhesive layers 326 may be less than the height H2 of the upper molding guide dams 320. The level and height H2 of the upper surfaces 320a of the upper molding guide dams 320 may be the same as those described in the example of FIG. 1B. In some implementations, the first adhesive layers 326 may be omitted, and the upper molding guide dams 320 may directly contact the lower molding guide patterns 310.

FIG. 1D is a diagram illustrating lower molding guide patterns and upper molding guide dams according to some implementations and corresponds to a cross-sectional view of the semiconductor package taken along line I-I′ of FIG. 1A. Hereinafter, redundant descriptions with those given above will be omitted for conciseness; descriptions provided with respect to FIGS. 1A-IC apply equally or similarly to corresponding elements of FIG. 1D, except where noted otherwise or suggested otherwise by context.

Referring to FIGS. 1A and 1D, the semiconductor package 10 may further include first adhesive layers 326 and second adhesive layers 316. The second adhesive layers 316 may be disposed between the package substrate 100 and the lower molding guide patterns 310 respectively. The lower molding guide patterns 310 may be attached onto the upper surface 100a of the package substrate 100 through the second adhesive layers 316. The second adhesive layers 316 may include, for example, an insulating polymer. The thickness of the second adhesive layers 316 may be less than the height H1 of the lower molding guide patterns 310. The level and height H1 of the upper surfaces of the lower molding guide patterns 310 may be the same as those described in the example of FIG. 1B.

The first adhesive layers 326 may be respectively disposed on the lower surfaces of the upper molding guide dams 320. The first adhesive layers 326 may be the same as those described in the example of FIG. 1C.

In some implementations, at least one of the second adhesive layers 316 and/or the first adhesive layers 326 may be omitted.

FIG. 1E is a diagram illustrating a substrate, lower molding guide patterns, and upper molding guide dams according to some implementations and corresponds to a cross-sectional view of the semiconductor package taken along line I-I′ of FIG. 1A. Hereinafter, redundant descriptions with those given above will be omitted for conciseness; descriptions provided with respect to FIGS. 1A-ID apply equally or similarly to corresponding elements of FIG. 1E, except where noted otherwise or suggested otherwise by context.

Referring to FIG. 1E, each of the upper molding guide dams 320 may be connected to (e.g., in contact with) a lower molding guide pattern 310 corresponding thereto among the lower molding guide patterns 310 without an interface (e.g., gap or other layer(s)) therebetween and may include the same material as the lower molding guide pattern 310. The lower molding guide patterns 310 may be connected to (e.g., in contact with) the protection layer 130 without an interface therebetween and may include the same material as the protection layer 130. The lower molding guide patterns 310 may be integrally formed with the upper molding guide dams 320 and the protection layer 130. The lower molding guide patterns 310, the protection layer 130, and the upper molding guide dams 320 may include a solder resist material. In this case, the composition ratio of the solder resist material of the lower molding guide patterns 310 may be substantially equal to the composition ratio of the solder resist material of the protection layer 130 and may be substantially equal to the composition ratio of the solder resist material of the upper molding guide dams 320. The upper surface 100a of the package substrate 100 may correspond to the upper surface of the protection layer 130 spaced apart from the lower molding guide patterns 310.

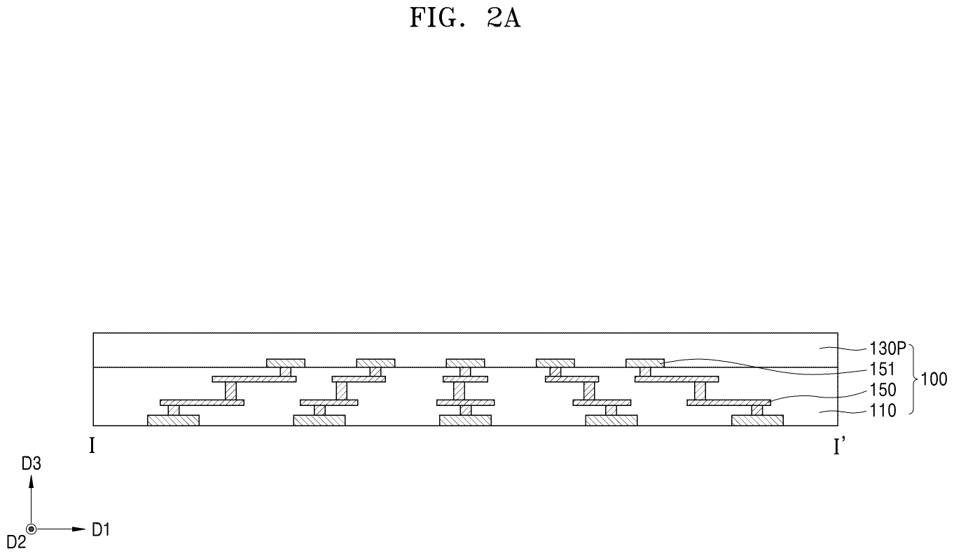

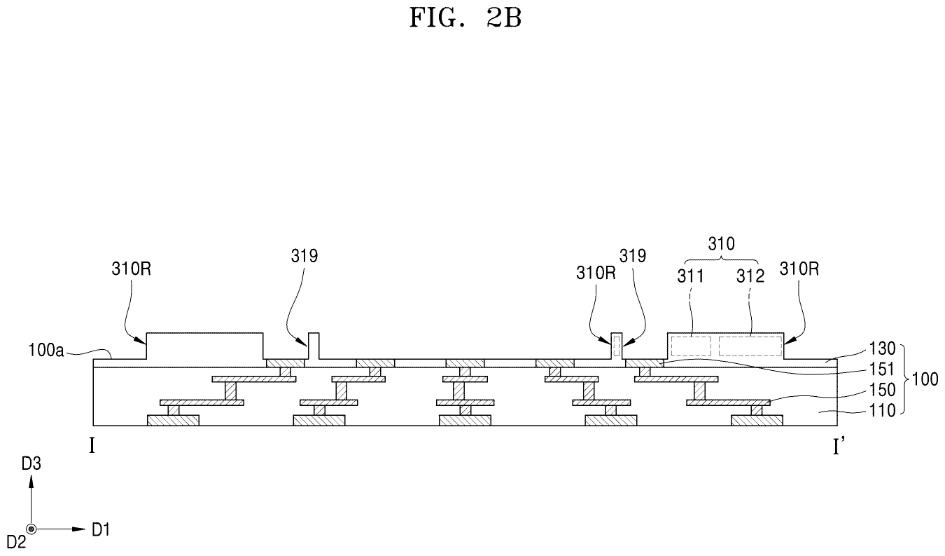

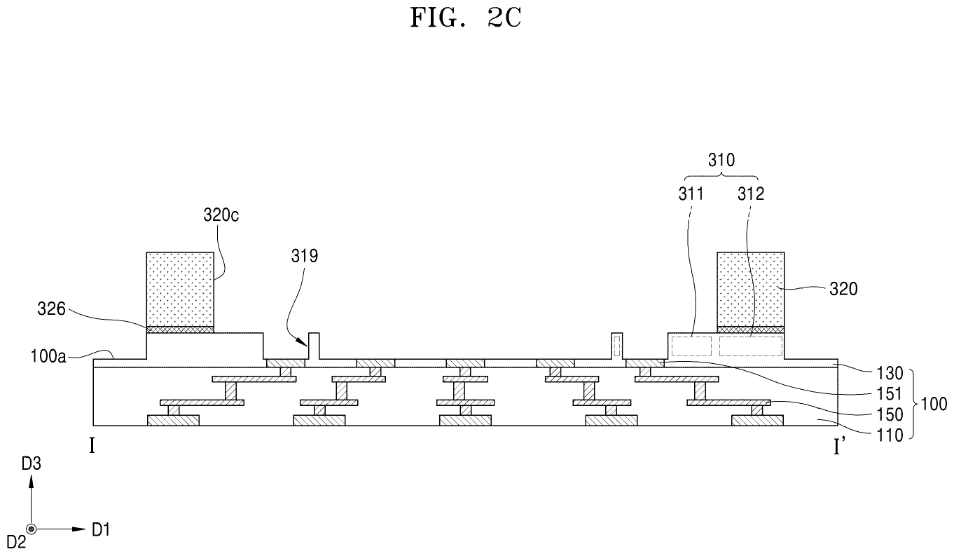

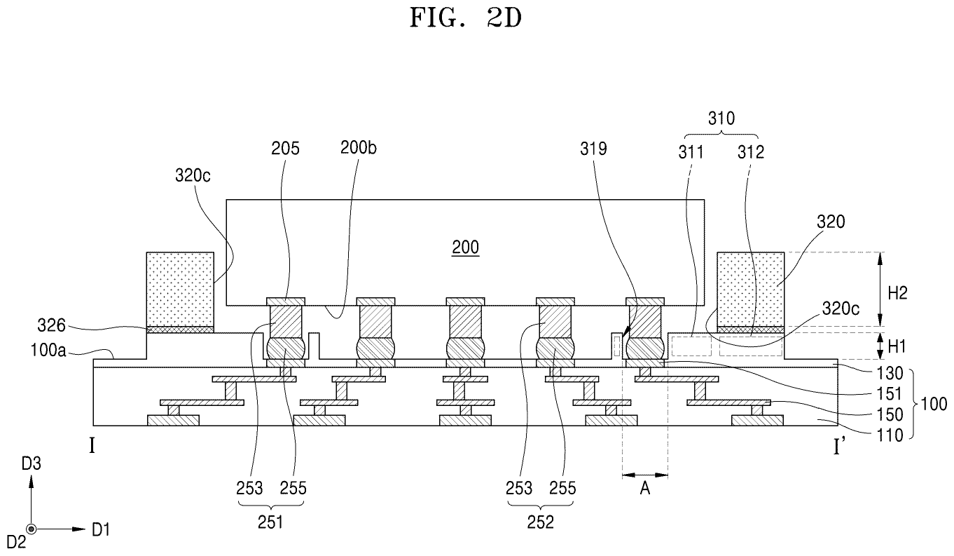

FIGS. 2A to 2D are diagrams for describing a process of manufacturing a semiconductor package according to some implementations. For example, the semiconductor package can be any of the semiconductor packages described with respect to FIGS. 1A to 1E.

Referring to FIG. 2A, a package substrate 100 may be prepared. The package substrate 100 may include a preliminary protection layer 130P in addition to the insulating layer 110, the substrate wires 150, and the upper substrate pads 151. The preliminary protection layer 130P may be provided over the upper surface of the insulating layer 110. As an example, the preliminary protection layer 130P may include a solder resist material. The upper surface of the preliminary protection layer 130P may be substantially flat; however, the configuration is not limited thereto.

Referring to FIGS. 2A and 2B, a portion of the preliminary protection layer 130P may be removed to form lower molding guide patterns 310 and a protection layer 130. For example, an upper portion of the preliminary protection layer 130P may be removed to form recess portions 310R. The recess portions 310R may define the lower molding guide patterns 310. For example, the lower molding guide patterns 310 may be formed between the recess portions 310R. The bottom surfaces of the recess portions 310R may correspond to the upper surface 100a of the package substrate 100 and the upper surface of the protection layer 130. A remaining lower portion of the preliminary protection layer 130P may form the protection layer 130. The lower molding guide patterns 310 and the protection layer 130 may be the same as those described in the examples of FIG. 1C. Openings 319 may be formed in the lower molding guide patterns 310. The openings 319 may be formed through a single process or a separate process from the lower molding guide patterns 310.

In some implementations, the lower molding guide patterns 310 may be separately formed and then attached to the protection layer 130 (e.g., at least partially instead of being formed by removing a portion of the preliminary protection layer 130P). In this case, the protection layer 130 and the lower molding guide patterns 310 may be the same as those described in the example of FIG. 1B.

As another example, the forming of the lower molding guide patterns 310 may include attaching the lower molding guide patterns 310 onto the upper surface 100a of the package substrate 100 by using the second adhesive layers 316 described in the example of FIG. 1D. In this case, the protection layer 130, the second adhesive layers 316, and the lower molding guide patterns 310 may be the same as those described in the example of FIG. 1D. In the following description of the process of FIGS. 2A to 2D, a case where the lower molding guide patterns 310 are connected to the protection layer 130 without an interface therebetween is illustrated for convenience; however, the process is not limited thereto, and can be applied to other configurations of the lower molding guide patterns 310 and the protection layer 130, e.g., as described in reference to FIGS. 1A to 1E.

The lower molding guide patterns 310 may include first portions 311 and second portions 312.

Referring to FIG. 2C, upper molding guide dams 320 may be formed over the second portions 312 of the lower molding guide patterns 310. The upper molding guide dams 320 may expose the upper surfaces of the first portions 311 of the lower molding guide patterns 310. The forming of the upper molding guide dams 320 may include attaching the upper molding guide dams 320 onto the upper surfaces of the lower molding guide patterns 310 by using a first adhesive layer 326.

In some implementations, the upper molding guide dams 320 may be directly disposed over the second portions 312 of the lower molding guide patterns 310. In this case, as illustrated in FIG. 1B, the lower surfaces of the upper molding guide dams 320 may directly physically contact the upper surfaces of the second portions 312 of the lower molding guide patterns 310.

Referring to FIG. 2D, a semiconductor chip 200 with first bumps 251 and second bumps 252 formed on the lower surface thereof may be prepared. The first and second bumps 251 and 252 may be provided over the lower surface 200b of the semiconductor chip 200 to be respectively connected to the chip pads 205. The semiconductor chip 200 may be provided over the package substrate 100 and the first portions 311 of the lower molding guide patterns 310. In some implementations, the position of the semiconductor chip 200 may be adjusted such that the first and second bumps 251 and 252 are vertically aligned with the upper substrate pads 151. The first bumps 251 may be vertically aligned with the openings 319. Herein, vertical alignment of an element with another element may mean alignment within an error range in the process.

The semiconductor chip 200 may descend. The semiconductor chip 200 may be disposed over the first portions 311 of the lower molding guide patterns 310. The semiconductor chip 200 may be disposed between inner walls 320c of the upper molding guide dams 320. The semiconductor chip 200 may be laterally spaced apart from the upper molding guide dams 320. By performing a reflow process on the first and second bumps 251 and 252, the first and second bumps 251 and 252 may be bonded to the upper substrate pads 151. The reflowing of the first and second bumps 251 and 252 may include heat-treating the first and second bumps 251 and 252. For example, the heat treatment may be performed at a temperature higher than or equal to the melting point of a solder ball 255. The solder ball 255 may be bonded to an upper substrate pad 151 corresponding thereto. Accordingly, the semiconductor chip 200 may be electrically connected to the package substrate 100 through the first and second bumps 251 and 252.

The molding layer 400 may be formed over the package substrate 100 to cover the sidewall of the semiconductor chip 200, the sidewalls of the lower molding guide patterns 310, the sidewalls of the upper molding guide dams 320, and the upper surfaces 320a of the upper molding guide dams 320. The molding layer 400 may further cover the upper surface of the semiconductor chip 200. The molding layer 400 may be formed by a molded underfill process. For example, the molding layer 400 may further extend between the package substrate 100 and the semiconductor chip 200 to fill the space between the bumps 251 and 252. For example, the manufacturing of the semiconductor package 10 may be completed by using the examples described above. Hereinafter, the forming of the molding layer 400 will be described in more detail.

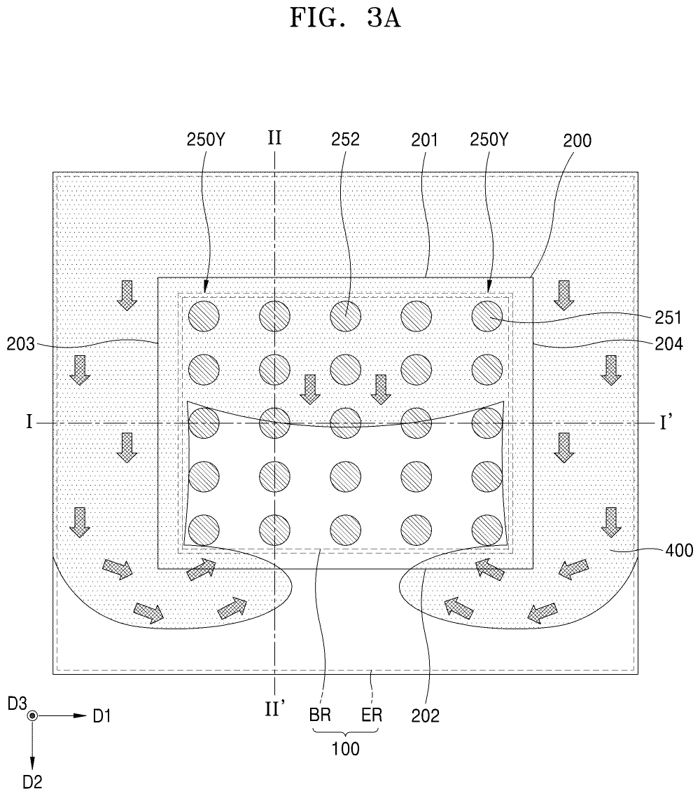

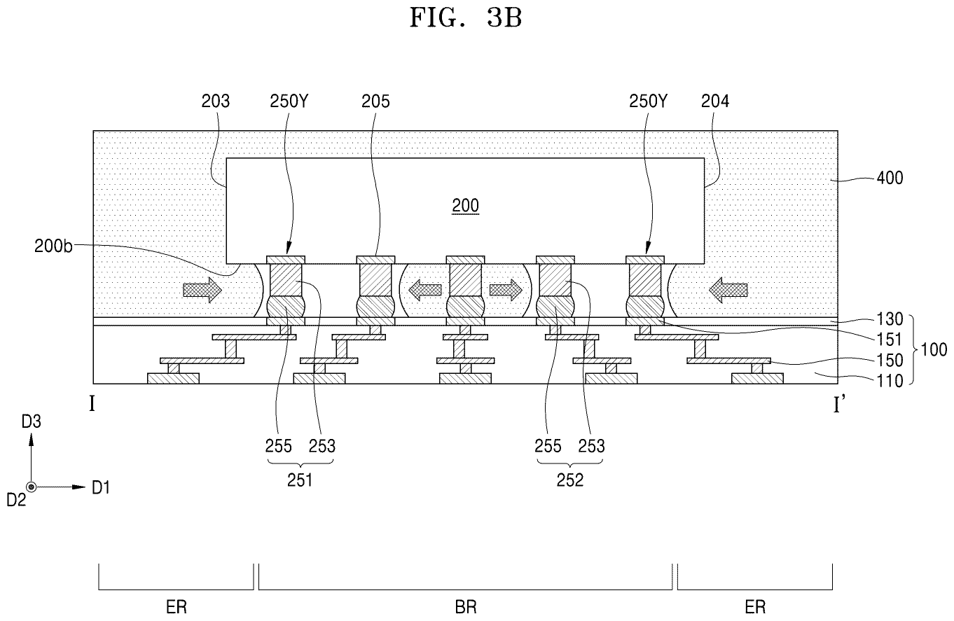

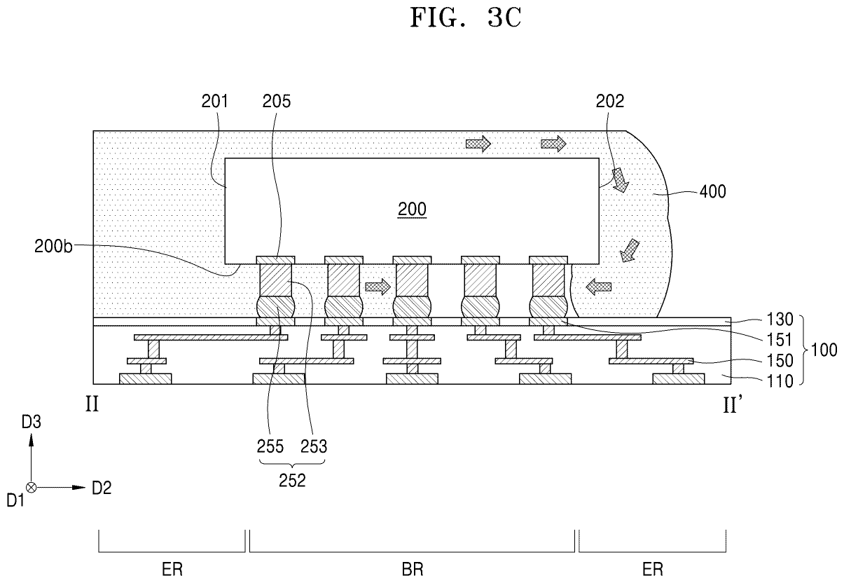

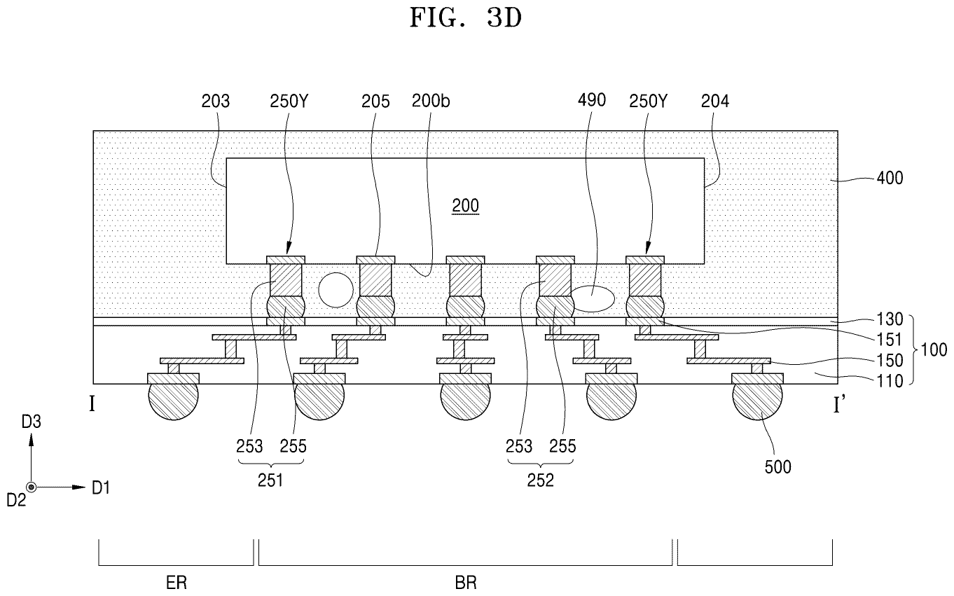

FIG. 3A is a plan view illustrating a process of forming a molding layer in a case where lower molding guide patterns and upper molding guide dams are omitted. FIG. 3B is a cross-sectional view illustrating a process of forming a molding layer in a case where lower molding guide patterns and upper molding guide dams are omitted, and corresponds to a cross-sectional view taken along line I-I′ of FIG. 3A. FIG. 3C is a cross-sectional view illustrating a process of forming a molding layer in a case where lower molding guide patterns and upper molding guide dams are omitted, and corresponds to a cross-sectional view taken along line II-II′ of FIG. 3A. FIG. 3D is a cross-sectional view illustrating a molding layer in a case where lower molding guide patterns and upper molding guide dams are omitted, and corresponds to a cross-sectional view taken along line I-I′ of FIG. 3A.

Referring to FIGS. 3A to 3D, forming a molding layer 400 may include providing a molding layer 400 over a package substrate 100 and performing a curing process on the molding layer 400. The molding layer 400 before the curing process may have fluidity. The molding layer 400 may flow from a first side of the package substrate 100 onto the upper surface 100a of the package substrate 100 as indicated by an arrow. As an example, the molding layer 400 may flow parallel to the second direction D2. The molding layer 400 may flow from a first side surface 201 of the semiconductor chip 200 onto the lower surface 200b and the upper surface of the semiconductor chip 200. In the plan view, the first side surface 201 of the semiconductor chip 200 may be adjacent to the first side of the package substrate 100 and may face in an opposite direction to the second direction D2. A second side surface 202 of the semiconductor chip 200 may face the first side surface 201 of the semiconductor chip 200 and may face in the second direction D2. A third side surface 203 and a fourth side surface 204 of the semiconductor chip 200 may be adjacent to the first side surface 201 and the second side surface 202 of the semiconductor chip 200. The fourth side surface 204 of the semiconductor chip 200 may face the third side surface 203.

The package substrate 100 may include a bump area BR and an edge area ER. The bump area BR of the package substrate 100 may include areas in which the bumps 251 and 252 are provided and areas between the bumps 251 and 252. The edge area ER of the package substrate 100 may surround the bump area BR in the plan view. The edge area ER of the package substrate 100 may be spaced apart from the bumps 251 and 252.

The movement speed of the molding layer 400 in the edge area ER of the package substrate 100 may be higher than the movement speed of the molding layer 400 in the bump area BR of the package substrate 100. Also, the movement speed of the molding layer 400 passing through the first bumps 251 of the outermost columns 250Y may be higher than the movement speed of the molding layer 400 passing through the second bumps 252. Accordingly, the molding layer 400 may flow in toward the second bumps 252 from the outer sides of the first bumps 251 of the outermost columns 250Y. For example, as illustrated in FIG. 3B, the molding layer 400 may flow from the third side surface 203 and the fourth side surface 204 of the semiconductor chip 200 into the space between the package substrate 100 and the lower surface 200b of the semiconductor chip 200. Due to the first and second bumps 251 and 252, the movement speed of the molding layer 400 on the lower surface 200b of the semiconductor chip 200 may be lower than the movement speed of the molding layer 400 on the upper surface of the semiconductor chip 200. As illustrated in FIG. 3C, the molding layer 400 may flow back under the lower surface 200b of the semiconductor chip 200 after covering the second side surface 202 of the semiconductor chip 200. For example, a portion of the molding layer 400 may flow from the second side surface 202 of the semiconductor chip 200 along the lower surface 200b of the semiconductor chip 200 in an opposite direction to the second direction D2.

Accordingly, as illustrated in FIG. 3D, a void 490 may be trapped between two adjacent bumps among the bumps 251 and 252. After the molding layer 400 is cured, the void 490 may be formed in the molding layer 400 between the package substrate 100 and the semiconductor chip 200. The void 490 may be an empty space occupied by air. When an operation of the semiconductor package is performed, the air in the void 490 may expand with an increase in the temperature of the semiconductor package. When the air in the void 490 bursts, the elements of the semiconductor package may be damaged.

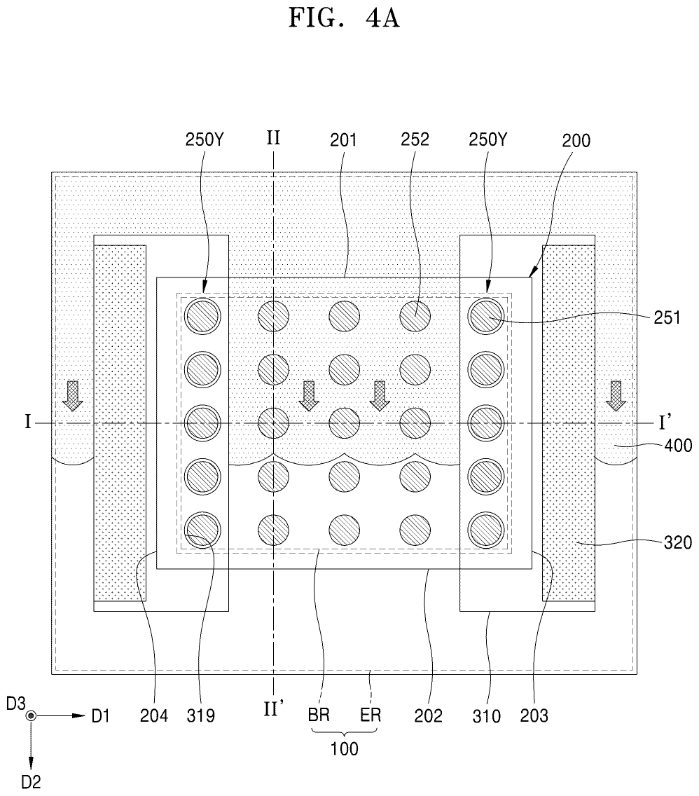

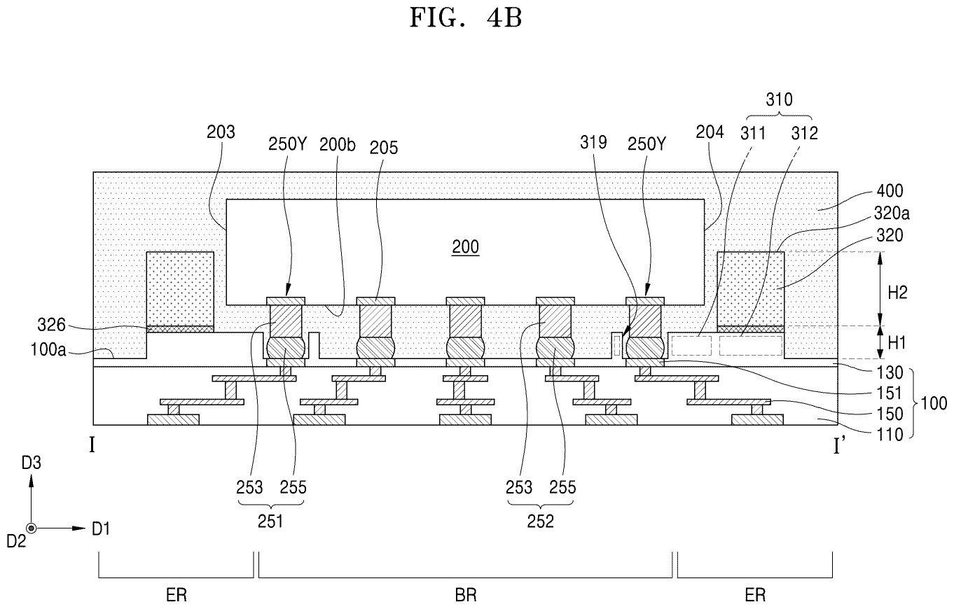

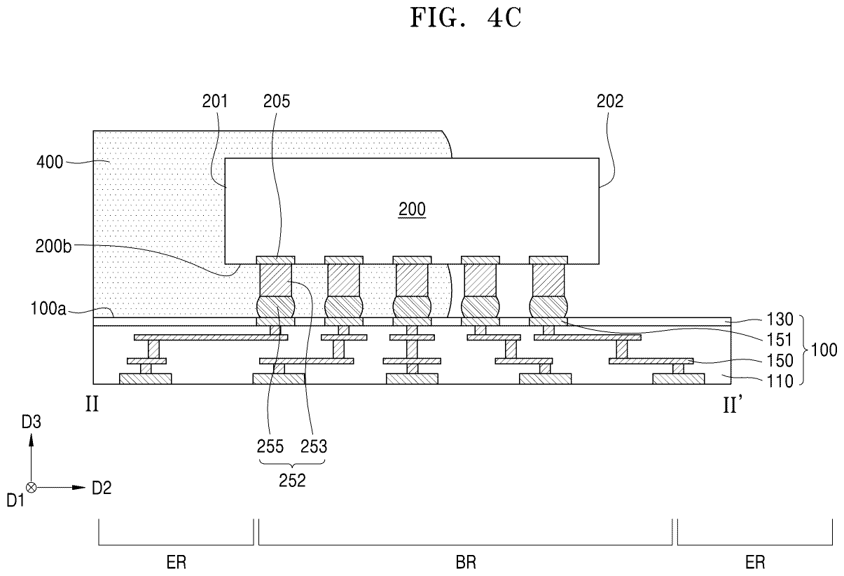

FIG. 4A is a plan view illustrating a process of forming a molding layer according to some implementations. FIG. 4B is a cross-sectional view illustrating a process of forming a molding layer according to some implementations and corresponds to a cross-sectional view taken along line I-I′ of FIG. 4A. FIG. 4C is a cross-sectional view illustrating a process of forming a molding layer according to some implementations and corresponds to a cross-sectional view taken along line II-II′ of FIG. 4A.

Referring to FIGS. 4A to 4C, the molding layer 400 may flow from the first side of the package substrate 100 onto the upper surface 100a of the package substrate 100 as indicated by an arrow.

In some implementations, because the lower molding guide patterns 310 and the upper molding guide dams 320 are provided, the difference between the movement speed of the molding layer 400 in the edge area ER of the package substrate 100 and the movement speed of the molding layer 400 in the bump area BR of the package substrate 100 may decrease. For example, as illustrated in FIG. 4A, the movement speed of the molding layer 400 in the edge area ER of the package substrate 100 may be equal or similar to the movement speed of the molding layer 400 in the bump area BR of the package substrate 100. Accordingly, the molding layer 400 over the edge area ER of the package substrate 100 may be entirely or substantially restricted or prevented from flowing into the bump area BR of the package substrate 100. A void 490 (see FIG. 3D) may be entirely or substantially restricted or prevented from being formed in the molding layer 400.

As illustrated in FIG. 4C, the molding layer 400 may flow from the first side surface 201 of the semiconductor chip 200 onto the lower surface 200b and the upper surface of the semiconductor chip 200. Because the lower molding guide patterns 310 and the upper molding guide dams 320 are provided, the movement speed of the molding layer 400 on the upper surface of the semiconductor chip 200 may be equal or similar to the movement speed of the molding layer 400 on the lower surface 200b of the semiconductor chip 200. Accordingly, the molding layer 400 may be entirely or substantially restricted or prevented from flowing back from the second side surface 202 of the semiconductor chip 200 onto the lower surface 200b of the semiconductor chip 200. Accordingly, formation of a void may be entirely or substantially restricted or prevented. Defects in the semiconductor package may be restricted/prevented/reduced. For example, in some implementations, even when the semiconductor package operates at high temperature for a long period, the semiconductor package may exhibit improved durability and reliability.

In some implementations, as illustrated in FIG. 4B, the upper molding guide dams 320 may be disposed laterally with respect to the third side surface 203 and the fourth side surface 204 of the semiconductor chip 200. The upper surfaces 320a of the upper molding guide dams 320 may be provided at a higher level than the lower surface 200b of the semiconductor chip 200. The upper molding guide dams 320 may restrict or prevent the molding layer 400 on the edge area ER of the package substrate 100 from flowing in toward the lower surface 200b of the semiconductor chip 200 after passing under the third and fourth side surfaces 203 and 204 of the semiconductor chip 200. In some implementations, because the height H2 of the upper molding guide dams 320 is 45 μm or more, the upper molding guide dams 320 may effectively restrict or prevent the molding layer 400 on the edge area ER of the package substrate 100 from flowing in onto the lower surface 200b of the semiconductor chip 200. Accordingly, formation of a void in the molding layer 400 may be further entirely or substantially restricted or prevented. It will be understood that, in some implementations, the foregoing advantages can be provided by other heights.

In some implementations, the lower molding guide patterns 310 may extend between the package substrate 100 and the lower semiconductor chip 200, and the first bumps 251 may be provided in the openings 319. Accordingly, the molding layer 400 may be restricted or prevented from flowing quickly on the outer sides of the first bumps 251. The movement speed of the molding layer 400 may become more uniform. For example, the movement speed of the molding layer 400 passing through the first bumps 251 may be equal or similar to the movement speed of the molding layer 400 passing through the second bumps 252. In some implementations, because the height H1 of the lower molding guide patterns 310 is 15 μm or more, the lower molding guide patterns 310 may more effectively restrict or prevent the molding layer 400 from flowing quickly on the outer sides of the first bumps 251. In some implementations, because the openings 319 have a diameter A of 150 μm or less, the movement speed of the molding layer 400 on the outer sides of the second bumps 252 may be more similar to the movement speed of the molding layer 400 on the outer sides of the first bumps 251. Accordingly, formation of a void may be further restricted or prevented. Thus, the semiconductor package may exhibit improved durability and reliability. It will be understood that, in some implementations, the foregoing advantages can be provided by other heights and/or diameters.

In some implementations, because the height H1 of the lower molding guide patterns 310 is 30 μm or less, the molding layer 400 may well fill a first gap area between the first portions 311 of the lower molding guide patterns 310 and the semiconductor chip 200. It will be understood that, in some implementations, the foregoing advantages can be provided by other heights.

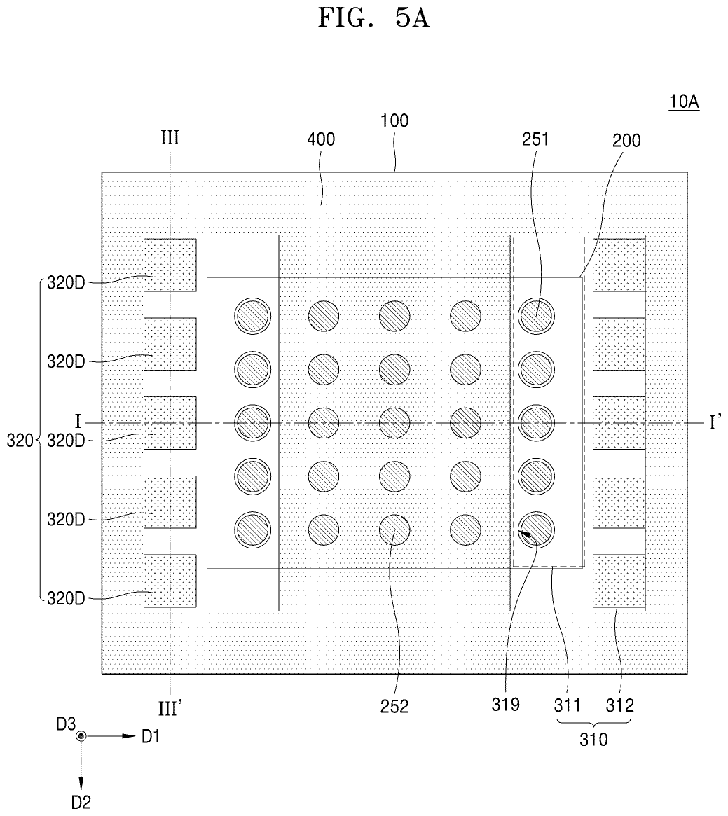

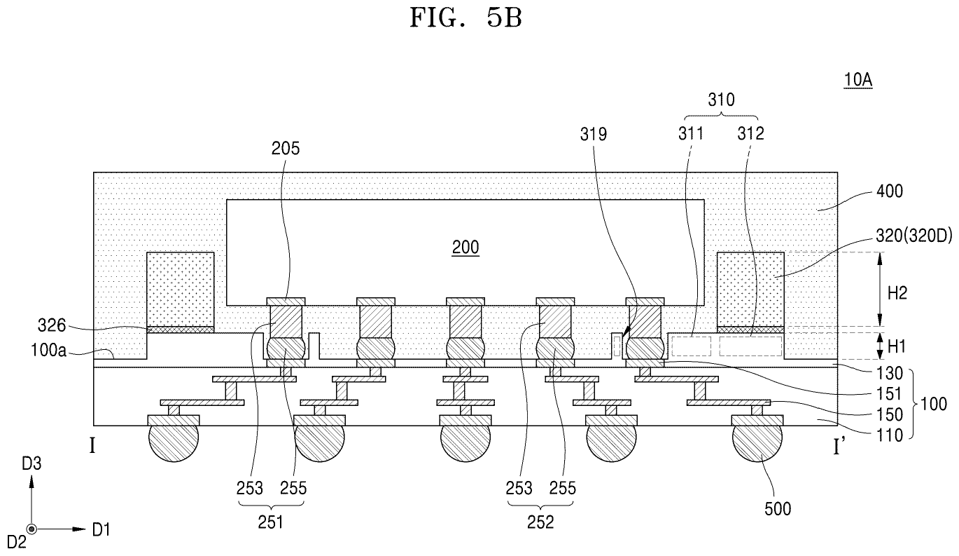

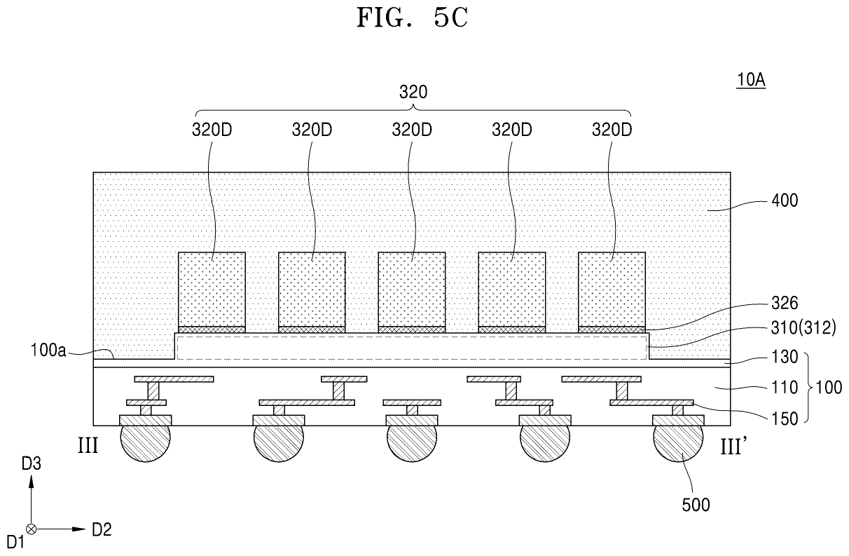

FIG. 5A is a plan view illustrating a semiconductor package according to some implementations. FIG. 5B is a cross-sectional view of the semiconductor package taken along line I-I′ of FIG. 5A. FIG. 5C is a cross-sectional view of the semiconductor package taken along line III-III′ of FIG. 5A.

Referring to FIGS. 5A to 5C, a semiconductor package 10A may include a package substrate 100, solder ball terminals 500, a semiconductor chip 200, first bumps 251, second bumps 252, lower molding guide patterns 310, upper molding guide dams 320, and a molding layer 400. The elements of the semiconductor package 10A, such as the package substrate 100, the solder ball terminals 500, the semiconductor chip 200, the bumps 251 and 252, the lower molding guide patterns 310, the upper molding guide dams 320, and the molding layer 400, may be substantially the same as those described in the examples of FIGS. 1A to 1D. For example, the upper molding guide dams 320 may be disposed over the second portions 312 of the lower molding guide patterns 310.

In some implementations, each of the upper molding guide dams 320 may include a plurality of dam portions 320D. The plurality of dam portions 320D may be disposed over a lower molding guide pattern 310 corresponding thereto among the lower molding guide patterns 310 and may be spaced apart from each other in the second direction D2.

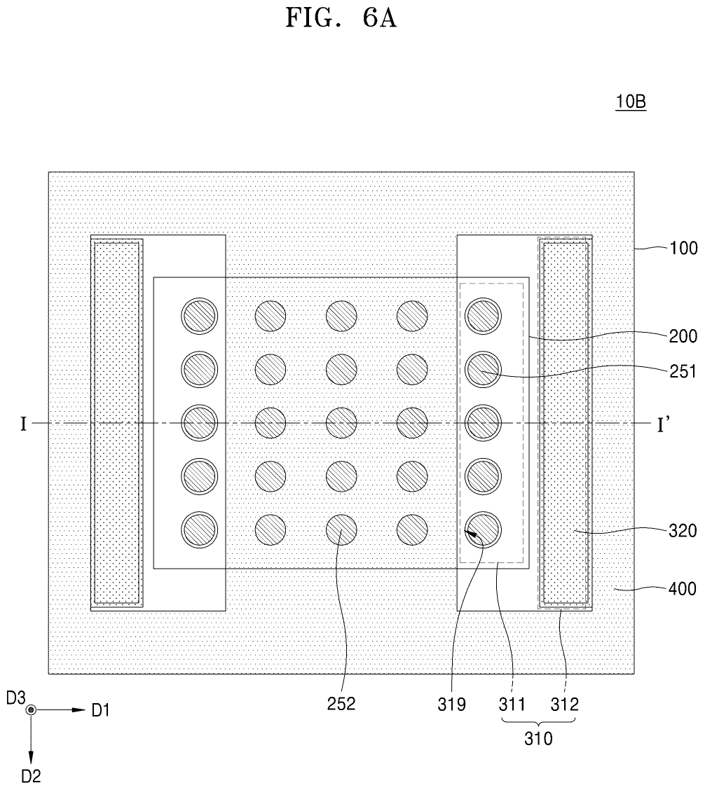

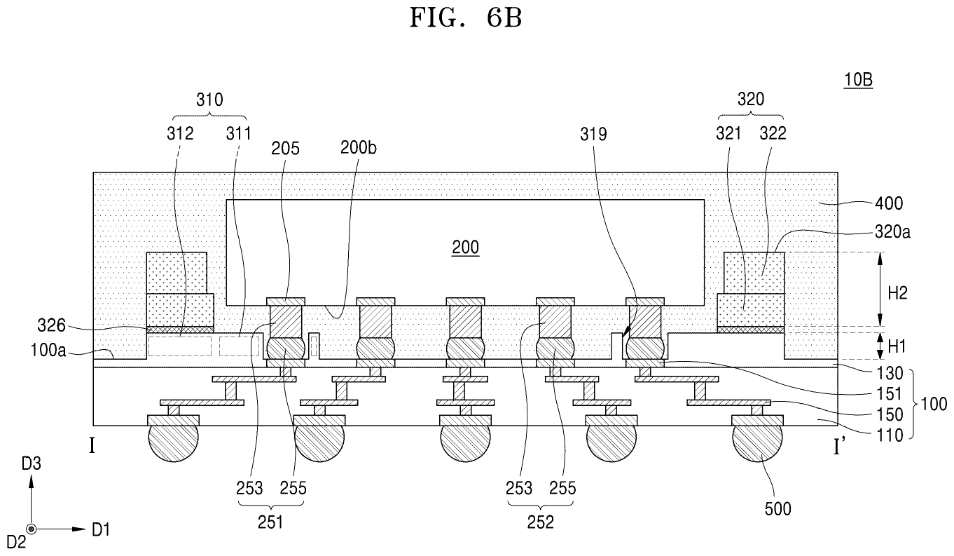

FIG. 6A is a plan view illustrating a semiconductor package according to some implementations. FIG. 6B is a cross-sectional view of the semiconductor package taken along line I-I′ of FIG. 6A.

Referring to FIGS. 6A and 6B, a semiconductor package 10B may include a package substrate 100, solder ball terminals 500, a semiconductor chip 200, first bumps 251, second bumps 252, lower molding guide patterns 310, upper molding guide dams 320, and a molding layer 400. These and other elements of the semiconductor package 10B may be substantially the same as corresponding elements of semiconductor package 10, except where indicated otherwise or suggested otherwise by context.

Each of the upper molding guide dams 320 may include a first upper molding guide dam 321 and a second upper molding guide dam 322. The first upper molding guide dam 321 may be disposed over the upper surface of the second portion 312 of one of the lower molding guide patterns 310. The second upper molding guide dam 322 may be disposed over the first upper molding guide dam 321. The upper surface 320a of the upper molding guide dam 320 may be the upper surface of the second upper molding guide dam 322. The upper surface of the second upper molding guide dam 322 may be provided at a level that is higher than the level of the lower surface 200b of the semiconductor chip 200 and is lower than the level of upper surface of the semiconductor chip 200. The second upper molding guide dam 322 may be disposed laterally with respect to the semiconductor chip 200. The width of the second upper molding guide dam 322 may be less than or equal to the width of the first upper molding guide dam 321. The height H2 of each of the upper molding guide dams 320 may be equal to the sum of the height of the first upper molding guide dam 321 and the height of the second upper molding guide dam 322. The first upper molding guide dam 321 and the second upper molding guide dam 322 may include an insulating polymer such as a solder resist material. As an example, the second upper molding guide dam 322 may include the same material as the first upper molding guide dam 321; however, the materials are not limited thereto. In some implementations, an adhesive layer may be further disposed between the first upper molding guide dam 321 and the second upper molding guide dam 322.

In some implementations, each of the upper molding guide dams 320 may further include a third upper molding guide dam. In this case, the third upper molding guide dam may be provided over the second upper molding guide dam 322. Each of the upper molding guide dams 320 may include a plurality of stacked layers. The number of stacked layers may be variously modified in various implementations.

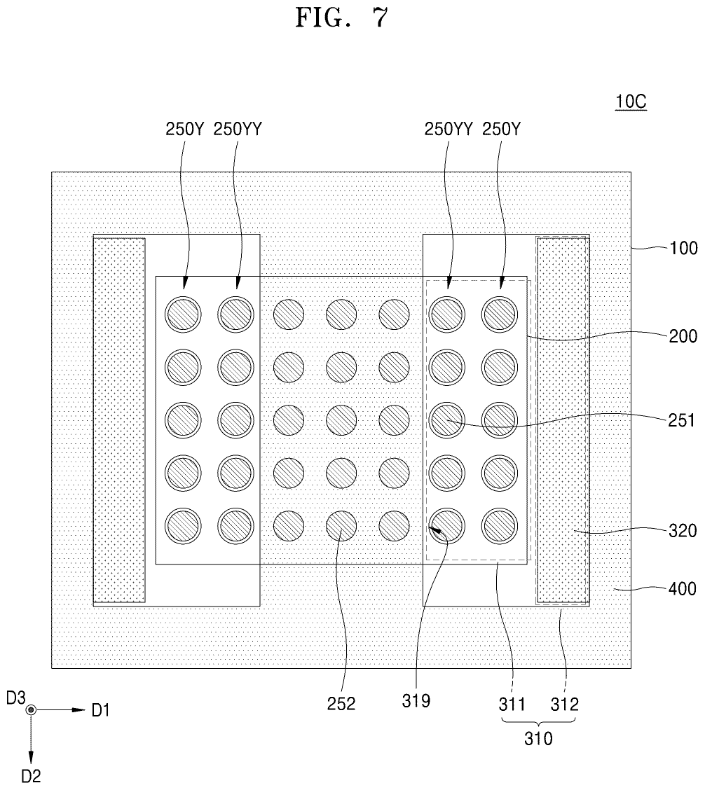

FIG. 7 is a plan view illustrating a semiconductor package according to some implementations.

Referring to FIG. 7, a semiconductor package 10C may include a package substrate 100, solder ball terminals 500, a semiconductor chip 200, first bumps 251, second bumps 252, lower molding guide patterns 310, upper molding guide dams 320, and a molding layer 400. These and other elements of the semiconductor package 10C may be substantially the same as corresponding elements of semiconductor package 10, except where indicated otherwise or suggested otherwise by context.

The first bumps 251 may include bumps in outer columns. For example, the first bumps 251 may include outermost columns 250Y and first outer columns 250YY. The outermost columns 250Y may include a first column and the last column. The first outer columns 250YY may be columns adjacent to the outermost columns 250Y. For example, the first outer columns 250YY may include a second column and a column adjacent to the last column. The first bumps 251 may be respectively provided in openings 319.

The second bumps 252 may be disposed between the first bumps 251. The second bumps 252 may be spaced apart from the openings 319 and the lower molding guide patterns 310. The second bumps 252 may be disposed between the inner walls of the lower molding guide patterns 310.

It will be understand that aspects of the various examples described herein may be combined with each other without departing from the scope of this disclosure. For example, characteristics of at least two examples among the examples of FIGS. 1A and 1B, the example of FIG. 1C, the example of FIG. 1D, the example of FIG. 1E, the example of FIGS. 5A to 5C, the example of FIGS. 6A and 6B, and the example of FIG. 7 may be combined with each other. As an example, the semiconductor package 10B of FIGS. 6A and 6B may further include the second adhesive layer 316 described in the example of FIG. 1D. In this case, the lower molding guide patterns 310 may be separate from the protection layer 130. As another example, each of the upper molding guide dams 320 of the semiconductor package 10C described in the example of FIG. 7 may include the dam portions 320D described in the example of FIGS. 5A to 5C.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While various examples have been particularly shown and described with reference to embodiments thereof, it will be understood that various changes in form and details may be made therein without departing from the spirit and scope of the following claims.

What is claimed is:

1. A semiconductor package comprising:
a package substrate;
a lower molding guide pattern disposed over the package substrate and comprising a first portion and a second portion;
a semiconductor chip disposed over an upper surface of the package substrate and over an upper surface of the first portion of the lower molding guide pattern;
an upper molding guide dam over the second portion of the lower molding guide pattern; and
a molding layer covering a side surface of the semiconductor chip and extending between the package substrate and a lower surface of the semiconductor chip,
wherein the upper molding guide dam is arranged laterally with respect to the semiconductor chip.

2. The semiconductor package of claim 1, wherein an upper surface of the upper molding guide dam is arranged at a higher level than the lower surface of the semiconductor chip.

3. The semiconductor package of claim 2, wherein the upper surface of the upper molding guide dam is provided at a lower level than an upper surface of the semiconductor chip.

4. The semiconductor package of claim 1, comprising bumps between the package substrate and the semiconductor chip,
wherein the first portion of the lower molding guide pattern defines openings, and wherein the bumps comprise:
first bumps arranged at the openings; and
second bumps spaced laterally apart from the lower molding guide pattern and the openings.

5. The semiconductor package of claim 4, wherein the bumps are arranged in a plurality of columns spaced apart from one another in a first lateral direction parallel to a top surface of the package substrate, each column of the plurality of columns including multiple bumps spaced apart from one another in a second lateral direction perpendicular to the first lateral direction, and
wherein the first bumps comprise bumps in an outermost column in the first lateral direction of the plurality of columns.

6. The semiconductor package of claim 4, wherein the molding layer is arranged between the bumps, and
wherein the molding layer extends between the upper surface of the first portion of the lower molding guide pattern and the lower surface of the semiconductor chip.

7. The semiconductor package of claim 1, comprising an adhesive layer arranged between the lower molding guide pattern and the upper molding guide dam.

8. The semiconductor package of claim 1, wherein the package substrate comprises a protection layer, and
wherein the lower molding guide pattern is in contact with the protection layer and comprises a same material as the protection layer.

9. The semiconductor package of claim 1, wherein the lower molding guide pattern extends in a first lateral direction parallel to a top surface of the package substrate, and
wherein the upper molding guide dam comprises a plurality of dam portions, the plurality of dam portions spaced apart from one another in the first lateral direction over the lower molding guide pattern.

10. The semiconductor package of claim 1, wherein an upper surface of the lower molding guide pattern is provided at a lower level than the lower surface of the semiconductor chip.

11. A semiconductor package comprising:
a substrate;
lower insulating patterns arranged over the substrate and spaced apart from one another in a first direction;
upper insulating patterns provided over the lower insulating patterns and spaced apart from one another in the first direction;
a semiconductor chip arranged over an upper surface of the substrate and between inner walls of the upper insulating patterns;
bumps between the substrate and the semiconductor chip; and
a molding layer covering a sidewall of the semiconductor chip and extending between the bumps,
wherein each of the lower insulating patterns comprises:
a first portion arranged between the substrate and the semiconductor chip; and
a second portion spaced laterally apart from the semiconductor chip and overlapping one of the upper insulating patterns in a plan view.

12. The semiconductor package of claim 11, wherein upper surfaces of the upper insulating patterns are arranged at a higher level than a lower surface of the semiconductor chip, and
wherein upper surfaces of the lower insulating patterns are arranged at a lower level than the lower surface of the semiconductor chip.

13. The semiconductor package of claim 11, wherein the lower insulating patterns define openings passing through upper surfaces and lower surfaces of the lower insulating patterns,
wherein the bumps comprise:
first bumps arranged at the openings and forming outermost columns, and
second bumps spaced apart from the lower insulating patterns and the openings, and
wherein the second bumps are arranged between the first bumps.

14. The semiconductor package of claim 11, wherein each of the upper insulating patterns comprises:
a first upper molding guide dam; and
a second upper molding guide dam over the first upper molding guide dam,
wherein an upper surface of the second upper molding guide dam is arranged at a higher level than a lower surface of the semiconductor chip.

15. The semiconductor package of claim 11, wherein one of the upper insulating patterns is formed integrally with one of the lower insulating patterns.

16. A semiconductor package comprising:
a package substrate comprising an insulating layer, substrate wiring, and a protection layer;
solder ball terminals on a lower surface of the package substrate;
lower molding guide patterns arranged over an upper surface of the package substrate and spaced apart from one another in a first direction;
upper molding guide dams disposed over the lower molding guide patterns and spaced apart from one another in the first direction;
a semiconductor chip arranged over the upper surface of the package substrate between the upper molding guide dams;
bumps arranged between the upper surface of the package substrate and a lower surface of the semiconductor chip and electrically connected to the package substrate and the semiconductor chip; and
a molding layer arranged over the upper surface of the package substrate and covering a side surface of the semiconductor chip,
wherein the molding layer extends under the lower surface of the semiconductor chip to cover sidewalls of the bumps,
wherein each of the lower molding guide patterns comprises
a first portion between the substrate and the semiconductor chip; and
a second portion spaced apart from the semiconductor chip and overlapping one of the upper molding guide dams in a plan view,
wherein an upper surface of the first portion of each of the lower molding guide patterns is arranged at a lower level than the lower surface of the semiconductor chip, and
wherein upper surfaces of the upper molding guide dams are provided at a level that is higher than or equal to a level of the lower surface of the semiconductor chip and is lower than a level of an upper surface of the semiconductor chip.

17. The semiconductor package of claim 16, wherein the first portion of each of the lower molding guide patterns defines openings,
wherein the bumps comprise
first bumps arranged at the openings; and
second bumps spaced apart from the lower molding guide patterns and the openings,
wherein the first bumps comprise bumps in an outermost column that extends in a second direction that is parallel to the upper surface of the package substrate and intersects the first direction, and
wherein the second bumps are arranged between inner walls of the lower molding guide patterns.

18. The semiconductor package of claim 17, wherein each of the lower molding guide patterns extends in the second direction, and
wherein each of the upper molding guide dams extends in the second direction.

19. The semiconductor package of claim 16, comprising adhesive layers arranged between the lower molding guide patterns and the upper molding guide dams,
wherein the lower molding guide patterns in contact with the protection layer and comprise a same solder resist material as the protection layer.

20. The semiconductor package of claim 16, wherein a height of the lower molding guide patterns is 15 μm to 30 μm, and
wherein a height of the upper molding guide dams is 45 μm to 300 μm.
